(19) United States
(12) Patent Application Publication
(10) Pub. No.: US 2017/0314131 A1
(43) Pub. Date: Nov. 2, 2017

(54) GAS DISTRIBUTING INJECTOR APPLIED IN MOCVD REACTOR

(71) Applicant: HERMES-EPITEK CORPORATION, TAIPEI CITY (TW)

(72) Inventors: Po-Jung Lin, Hsinchu (TW); Che-Lin Chen, Hsinchu (TW); Chang-Da Tsai, Kaohsiung City (TW); Bu-Chin Chung, Hsinchu (TW)

(21) Appl. No.: 15/467,987

(22) Filed: Mar. 23, 2017

(30) Foreign Application Priority Data
Apr. 27, 2016 (TW) 105113169

(51) Int. Cl. C23C 16/455; C23C 16/18

(52) U.S. Cl. CPC C23C 16/45576; C23C 16/18; C23C 16/45574

(57) ABSTRACT

The present invention relates to a gas distributing injector applied in MOCVD reactor. The gas distributing injector comprises at least one gas distributing layer for distributing different gases. The distributing layer is a single-layered structure. The distributing layer comprises a disk-shaped body, a plurality of first gas channels, a plurality of second gas channels, and a plurality of third gas channels. The first gas channels, the second gas channels, and the third gas channels are radially distributed on the same plane in the disk-shaped body. Different gases are distributed or fed into different gas channels (such as the first gas channels, the second gas channels, and the third gas channels) and transported by different gas channels. Through different gas channels, different gases are transversely injected into the MOCVD reactor on the same plane respectively. Therefore, the gas distributing injector of this invention can distribute different gases by a single-layered structure.

### CROSS-REFERENCE TO RELATED APPLICATIONS

The entire contents of Taiwan Patent Application No. 105113169, filed on Apr. 27, 2016, from which this application claims priority, are incorporated herein by reference.

### BACKGROUND OF THE INVENTION

### 1. Field of the Invention

The present invention relates to deposition system and more particularly relates to gas distributing injector applied in MOCVD reactor.

### 2. Description of Related Art

During the manufacturing process of electronic and optoelectronic device, Metal-Organic Chemical Vapor Deposition (MOCVD) is typically employed to form one or more thin-films on surface of a substrate or wafer. Group III elements and group V elements are fed into a planetary MOCVD reactor via an injector, so as to form group III-V compound thin-film on the substrate or wafer. During the formation of the thin-films, the planetary MOCVD reactor generally uses a triple injector to feed the gases. FIG. 1 is side view showing a conventional triple injector 10. The triple injector 10 mainly includes an upper channel 12, a middle channel 14, and a lower channel 16 arranged at a high level, a middle level, and a low level, respectively. Hydrogen or nitrogen gas is used as the carrier gas for the three channels. In detail, group V gases, e.g., ammonia (NH₃), are injected through the upper channel 12 and the lower channel 16, and group III gases, e.g., Trimethylgallium (TMGa) or trimethyl aluminum (TMAl), are injected through the middle channel 14. Then group V gases meets group III gases at the region on which the substrate or wafer is placed, the group III gases reacts with group V gases and thus to form an compound thin-film on the surface of the substrate or wafer 18.

Because various gases are distributed through the same triple injector 10, a multi-layered configuration including the upper channel 12, the middle channel 14, and the lower channel 16 is designed for this need. However, the triple injector 10 distributes the gases into the MOCVD reactor in a multi-layered manner, which will result in a considerable volume of the triple injector 10. In addition, the distributed gas from each channel needs a period of time for mixing with other gases when it diffuses vertically and transversely. The reaction is initiated after the gases are totally mixed and the compound thin-film then be formed on the surface of the substrate or the wafer.

Accordingly, a primary need is required to improve the diffusion efficiency of the gases.

### SUMMARY OF THE INVENTION

In one general aspect, the present invention relates to a device of a chemical deposition system and more particularly, relates to a gas distributing injector applied in a MOCVD reactor to improve the diffusion efficiency of the gases and reduce the dimensions of the device.

According to an embodiment of this invention, a gas distributing injector applied in a Metal-Organic Chemical Vapor Deposition (MOCVD) reactor is provided with a gas distributing layer having a disk-shaped body, a plurality of first gas channels, a plurality of second gas channels, and a plurality of third gas channels. The gas distributing layer is used for transversely distributing various gases through a same plane. The disk-shaped body includes a hole at its center, the various gases are fed via the hole, and a gas distributing device is placed within the hole. The first gas channels are radially outwardly arranged from the center of the disk-shaped body to the periphery of the disk-shaped body, for transversely distributing a first gas of the various gases from the center of the disk-shaped body to the periphery of the disk-shaped body. The second gas channels are radially outwardly arranged from the center of the disk-shaped body to the periphery of the disk-shaped body, for transversely distributing a second gas of the various gases from the center of the disk-shaped body to the periphery of the disk-shaped body. The third gas channels are radially outwardly arranged from the center of the disk-shaped body to the periphery of the disk-shaped body, for transversely distributing a third gas of the various gases from the center of the disk-shaped body to the periphery of the disk-shaped body. Wherein the first gas channels, the second gas channels, and the third gas channels are symmetrically arranged within the disk-shaped body and are arranged on the same plane, and the various gases are transversely distributed through the same plane.

In an embodiment, the first gas is a group III gas, the second gas is a group V gas, the third gas is a group V gas, and hydrogen gas or nitrogen gas is used as a carrier gas for the first gas, the second gas, and the third gas.

In an embodiment, at least one of the second gas channels or at least one of the third gas channels is interposed between every two of the first gas channels.

In an embodiment, at least one of the second gas channels and at least one of the third gas channels are interposed between every two of the first gas channels.

In an embodiment, the gas distributing layer further comprises a plurality partitions to separate the first gas channels, the second gas channels, and the third gas channels and control a diffusion time of the various gases.

In an embodiment, the first gas channels, the second gas channels, the third gas channels, and the partitions are alternately arranged by a first repeating period and a second repeating period, and wherein the first repeating period comprises at least one first gas channel and at least one second gas channel interposed between two partitions, and the second repeating period comprises at least one first gas channel and at least one third gas channel interposed between two partitions.

In an embodiment, the gas distributing injector further comprises a second gas distributing layer stacked on the gas distributing layer, and the second gas distributing layer comprises a disk-shaped body, a plurality of first gas channels, a plurality of second gas channels, and a plurality of third gas channels.

Accordingly, embodiments of the present invention provide gas distributing injector in which the various (reactant gases) are transversely injected into the MOCVD reactor on a same plane. The gas distributing injector has a compact size and the reactant gases are mixed soon on the same plane by diffusion because the vertical mixing is unnecessary.

### BRIEF DESCRIPTION OF THE DRAWINGS

FIG. 1 is a side view showing a conventional triple injector for a MOCVD reactor.

FIG. 2 shows both top view and side view of a gas distributing injector according to an embodiment of the present invention.

FIGS. 3A and 3B both show top view and side view of a gas distributing injector according to another embodiment of the present invention.

FIGS. 4A and 4B both show top view and side view of a gas distributing injector according to another embodiment of the present invention.

FIGS. 5A and 5B both shows top view and side view of a gas distributing injector according to another embodiment of the present invention.

FIG. 6 shows both top view and side view of a gas distributing injector with partition according to another embodiment of the present invention.

FIG. 7 shows both top view and side view of a gas distributing injector with partition according to another embodiment of the present invention.

FIGS. 8A and 8B both show top view and side view of a gas distributing injector with partition according to another embodiment of the present invention.

FIGS. 9A and 9B both show top view and side view of a gas distributing injector with partition according to another embodiment of the present invention.

FIG. 10 shows a side view of a gas distributing injector with inclined gas distributing channel according to another embodiment of the present invention.

FIGS. 11A and 11B both show a side view of a gas distributing injector according to another embodiment of the present invention.

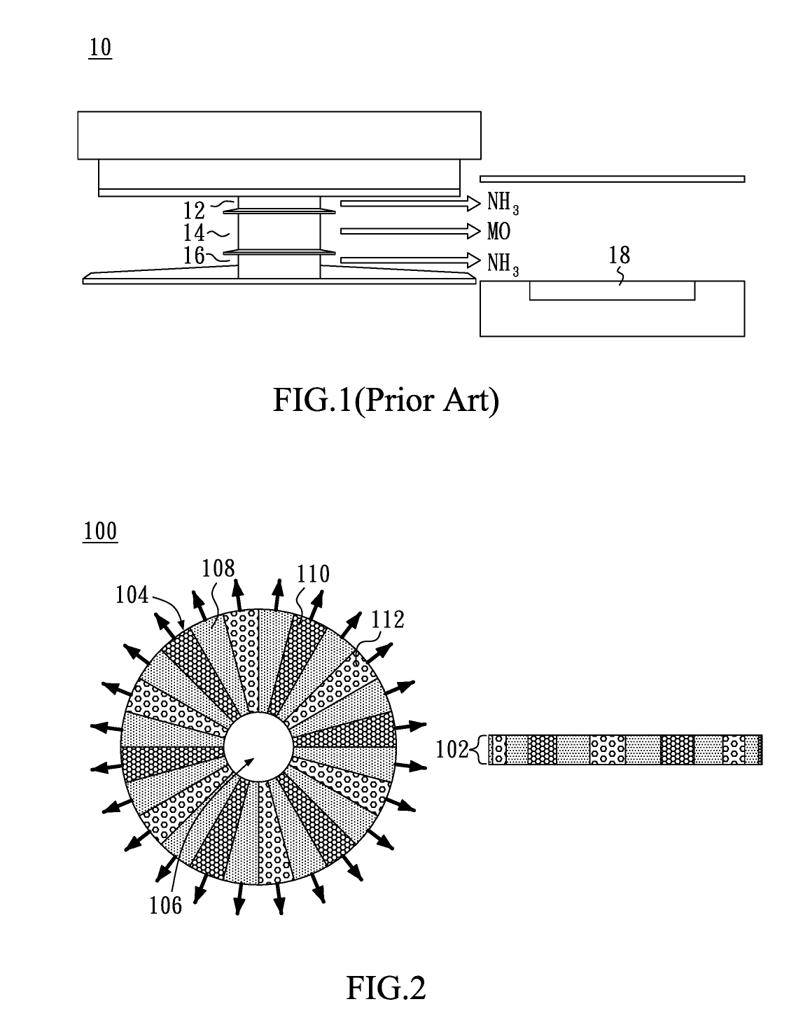

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components, for example, gas distributing layer, gas channel, etc., may be greater or less than that disclosed, except where expressly restricting the amount of the components. In addition, some of the disclosed components may not be drawn in scale, and some portion of the disclosed components may be magnified or simplified to stress the features of the invention. Wherever possible, the same or similar reference numbers are used in drawings and the description to refer to the same or like parts.

Referring to FIG. 2, a top view (left) and a side view (right) of a gas distributing injector 100 are provided according to an embodiment of the present invention. The gas distributing injector 100 includes a gas distributing layer 102, which has a single layer configuration for distributing different (reactant) gases transversely through a same plane. The gas distributing layer 102 comprises a disk-shaped body 104, a plurality of first gas channel 108 for distributing a first (reactant) gas, a plurality of second gas channel 110 for distributing a second (reactant) gas, and a plurality of third gas channel 112 for distributing a third (reactant) gas. A central portion of the disk-shaped body 104 or the gas distributing layer 102 includes a hole 106 used as a gas supplying source. A gas distributing device (not shown) is placed within the hole 106 and the first gas, the second gas, and the third gas are supplied through the hole 106. The gas distributing device can distribute a selected (reactant) gas, e.g., the first gas, the second gas, or the third gas, to a corresponded specific gas channel, e.g., the first gas channel 108, the second gas channel 110, or the third gas channel 112. The distributing device can be any suitable gas distributing device used in the art, and the detail of which is omitted for simplicity.

The first gas channels 108 are separately arranged within the disk-shaped body 104 and each of the first gas channels 108 is radially outwardly extended from a center of the disk-shaped body 104 toward the periphery of the disk-shaped body 104. Each of the first gas channels 108 includes a gas inlet at the center of the disk-shaped body 104 and a gas outlet at the periphery of the disk-shaped body 104. The first gas channels 108 are used for distributing the first (reactant) gas. The first (reactant) gas is fed from the gas inlet and is sprayed from the gas outlet. Therefore, the first gas can be radially outwardly diffused to the MOCVD reactor.

Similarly, the second gas channels 110 are separately arranged within the disk-shaped body 104 and each of the second gas channels 110 is radially outwardly extended from a center of the disk-shaped body 104 toward the periphery of the disk-shaped body 104. Each of the second gas channels 110 includes a gas inlet at the center portion of the disk-shaped body 104 and a gas outlet at the periphery of the disk-shaped body 104. The second gas channels 110 are used for distributing the second (reactant) gas. The second (reactant) gas is fed from the gas inlet and is sprayed from the gas outlet. Therefore, the first gas can be radially outwardly diffused to the MOCVD reactor.

Similarly, the third gas channels 112 are separately arranged within the disk-shaped body 104 and each of the third gas channels 112 is radially outwardly extended from a center of the disk-shaped body 104 toward the periphery of the disk-shaped body 104. Each of the third gas channels 112 includes a gas inlet at the center portion of the disk-shaped body 104 and a gas outlet at the periphery of the disk-shaped body 104. The third gas channels 112 are used for distributing the third (reactant) gas. The third (reactant) gas is fed from the gas inlet and is sprayed from the gas outlet. Therefore, the third gas can be radially outwardly diffused to the MOCVD reactor.

In this embodiment, the first gas channels 108, the second gas channels 110, and the third gas channels 112 are radially distributed on the same plane within the disk-shaped body 104 in a symmetrical manner, so that the disk-shaped body 104 or the gas distributing layer 102 has a single-layered configuration. Wherein the first (reactant) gas comprises group III gases, for example, trimethylgallium (TMGa) or rimethylaluminum (TMAl), and the second (reactant) gas and the third (reactant) gas comprise group V gases, for example, ammonia gas (NH₃). Depending on the type of produced group III-V compound thin-film, the second gas and the third gas can be different group V gases. On the other hand, the second gas and the third gas can be a same group V gas. In addition, the flow rate of the second gas within the second gas channel can be different than the flow rate of the third gas within the third gas channel. Or, the flow rate of the second gas within the second gas channel is the same as the flow rate of the third gas within the third gas channel. One or more carrier gases, such as hydrogen gas or nitrogen gas, can be used for carrying the first (reactant) gas, the second (reactant) gas, and the third (reactant) gas within the first gas channel 108, the second gas channel 110, and the third gas channel 112.

Referring to FIG. 2, each second gas channel 110 is sandwiched by two first gas channels 108 next to the second gas channel 110, and each third gas channel 112 is also sandwiched by two first gas channels 108 next to the third gas channel 112. One second gas channel 110 or one third gas channel 112 is interposed between every two first gas channels 108. In addition, the arrangement of the gas channels can follow a rule. For example, the gas channels 108/110/112 can be arranged by a repeating period that orderly consists of one first gas channel 108, one second gas channel 110, one first gas channel 108, and one third gas channel 112. Alternatively, the gas channels 108/110/112 can be arranged by a repeating period that orderly consists of one first gas channel 108, one third gas channel 112, one first gas channel 108, and one second gas channel 110. In this embodiment, the number of the first gas channels 108, the second gas channels 110, and the third gas channels 112 is twelve, six, and six, respectively. However, the number of the first gas channels 108, the second gas channels 110, and the third gas channels 112 should not be limited. Modification of the number of the gas channels 108/110/112 should be within the scope of the present invention. In addition, there is no limited that one second gas channel 110 or one third gas channel 112 is interposed between every two first gas channels 108. The number of second gas channel 110 or third gas channel 112 sandwiched by the two first gas channel 108 can be one or more. That is, at least one second gas channel 110 or at least one third gas channel 112 is interposed between every two first gas channels 108.

When various (reactant) gases, such as the first gas, the second gas, and the third gas, are fed to the gas distributing injector 100, the gas distributing device (not shown) distributes the various (reactant) gases to the corresponded specific gas channels 108/110/112. In addition, the gas distributing device can adjust the flow rate or the volume of gas transported per unit of time of the various (reactant) gases according to the need of the MOCVD process. Different (reactant) gases can be adjusted by the gas distributing device to have different flow rate according the need of the MOCVD process. For example, the flow rate of the first gas within the first gas channels 108 may be different than the flow rate of the second gas within the second gas channels 108 and the flow rate of the third gas within the third gas channel. Because each gas channel, including each of the first gas channel 108, the second gas channel 110, and the third gas channel 112, transport the gas independently and does not communicate with other gas channels, the gas of each gas channel will not mix with other gases within the gas distributing layer 102 or the disk-shaped body 104. Because all of the first gas channels 108, the second gas channels 110, and the third gas channels 112 are arranged at a same plane, the first gas, the second gas, and the third gas are radially outwardly distributed from the center of the gas distributing layer 102 to the periphery of the gas distributing layer 102 and the distributions are carried out at the same plane. The reactant gases are transversely injected into the MOCVD reactor on a same plane. The reactant gases are mixed on the same plane by diffusion. Comparing with prior art, the reactant gases are mixed soon because the vertical mixing is unnecessary, such that the time needed for reacting can be reduced.

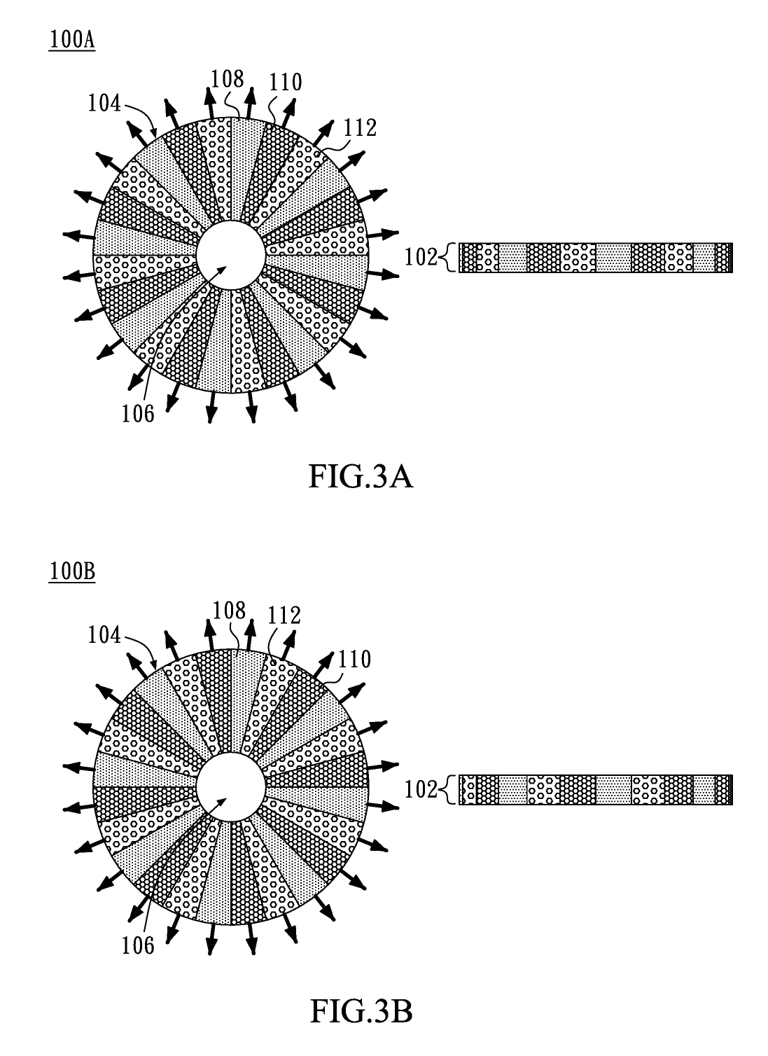

FIG. 2 shows the example that at least one second gas channel 110 or at least one third gas channel 112 is interposed between every two first gas channels 108. FIGS. 3A and 3B show another embodiment of the present invention that at least one second gas channel 110 and at least one third gas channel 112 are interposed between two first gas channels 108.

FIG. 3A shows both top view and side view of a gas distributing injector 100A according to another embodiment of the present invention. In this embodiment, one second gas channel 110 and one third gas channel 112 are interposed between every two first gas channels 108. The gas channels 108/110/112 are arranged by a repeating period that clockwise orderly consists of one first gas channel 108, one second gas channel 110, and one third gas channel 112.

FIG. 3B shows both top view and side view of a gas distributing injector 100B according to another embodiment of the present invention. In this embodiment, one third gas channel 112 and one second gas channel 110 are interposed between every two first gas channels 108. The gas channels 108/110/112 are arranged by a repeating period that clockwise orderly consists of one first gas channel 108, one third gas channel 112, and one second gas channel 110.

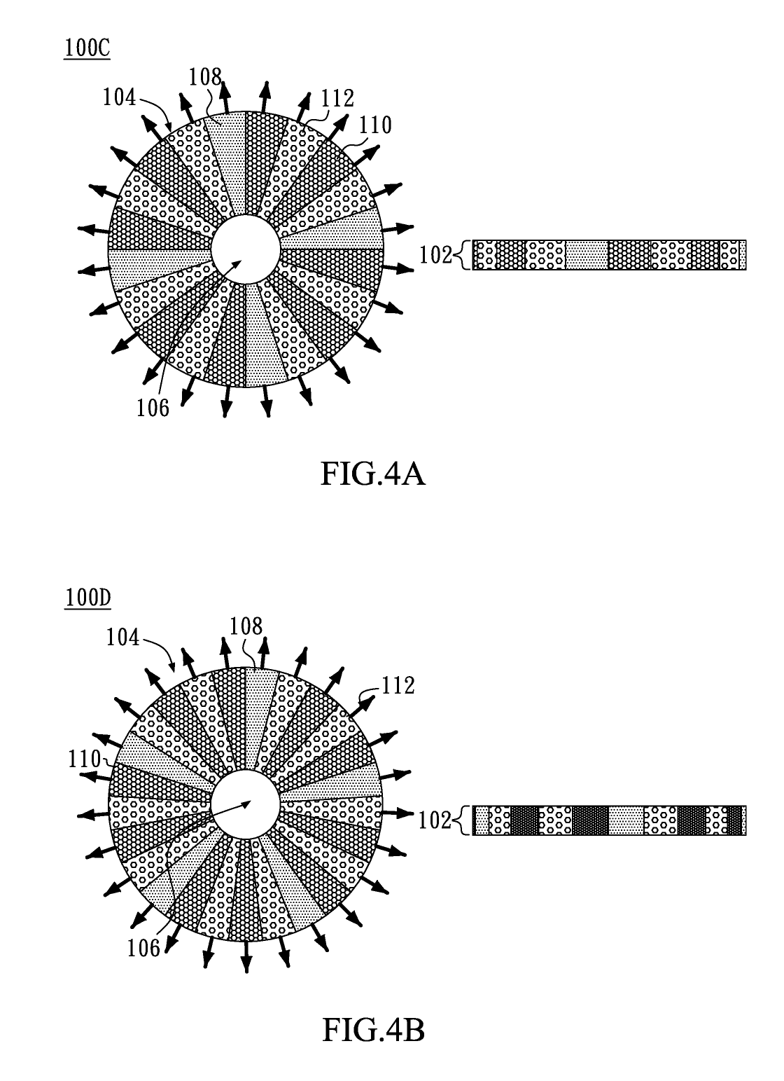

FIG. 3A and FIG. 3B show that one second gas channel 110 and one third gas channel 112 are interposed between every two first gas channels 108. However, the number of the second gas channel 110 and the number of the third gas channel 112 interposed between the every two first gas channels 108 can be two or more. FIG. 4A and FIG. 4B show such examples.

FIG. 4A shows both top view and side view of a gas distributing injector 100C according to another embodiment of the present invention. In this embodiment, two second gas channels 110 and two third gas channels 112 are interposed between every two first gas channels 108. The gas channels 108/110/112 are arranged by a repeating period that clockwise orderly consists of one first gas channel 108, one second gas channel 110, one third gas channel 112, one second gas channel 110, and one third gas channel 112.

FIG. 4B shows both top view and side view of a gas distributing injector 100D according to another embodiment of the present invention. In this embodiment, two third gas channels 112 and two second gas channels 110 are interposed between every two first gas channels 108. The gas channels 108/110/112 are arranged by a repeating period that clockwise orderly consists of one first gas channel 108, one third gas channel 112, one second gas channel 110, one third gas channel 112, and one second gas channel 110.

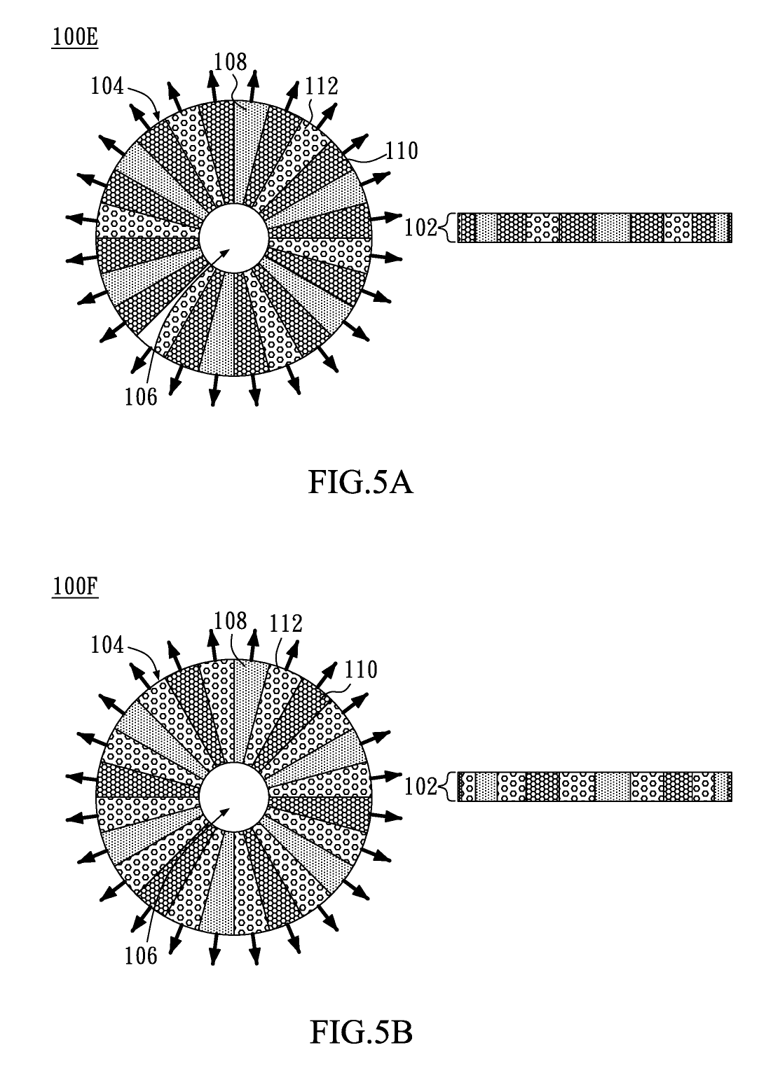

FIG. 5A shows both top view and side view of a gas distributing injector 100E according to another embodiment of the present invention. In this embodiment, two second gas channels 110 and one third gas channel 112 are interposed between every two first gas channels 108, and where the third gas channel 112 is interposed between the two second gas channels 110. The gas channels 108/110/112 are arranged by a repeating period that clockwise orderly consists of one first gas channel 108, one second gas channel 110, one third gas channel 112, and one second gas channel 110.

FIG. 5B shows both top view and side view of a gas distributing injector 100F according to another embodiment of the present invention. In this embodiment, two third gas channels 112 and one second gas channel 110 are interposed between every two first gas channels 108, and where the second gas channel 110 is interposed between the two third gas channels 112. The gas channels 108/110/112 are arranged by a repeating period that clockwise orderly consists of one first gas channel 108, one third gas channel 112, one second gas channel 110, and one third gas channel 112.

The embodiments of FIGS. 3A, 3B, 4A, 4B, 5A, and 5B show the examples that at least one second gas channel 110 and at least one third gas channel 112 are interposed between every two first gas channels 108. The number of the interposed second gas channel 110 and third gas channel 112 are not limited. Referring to FIG. 5A, the number of the third gas channel 112 interposed between the two second gas channels 110 should not be limited to one. Referring to FIG. 5B, the number of the second gas channel 110 interposed between the two third gas channels 112 should not be limited to one. Modification of the number of gas channels should be within the scope of the present invention.

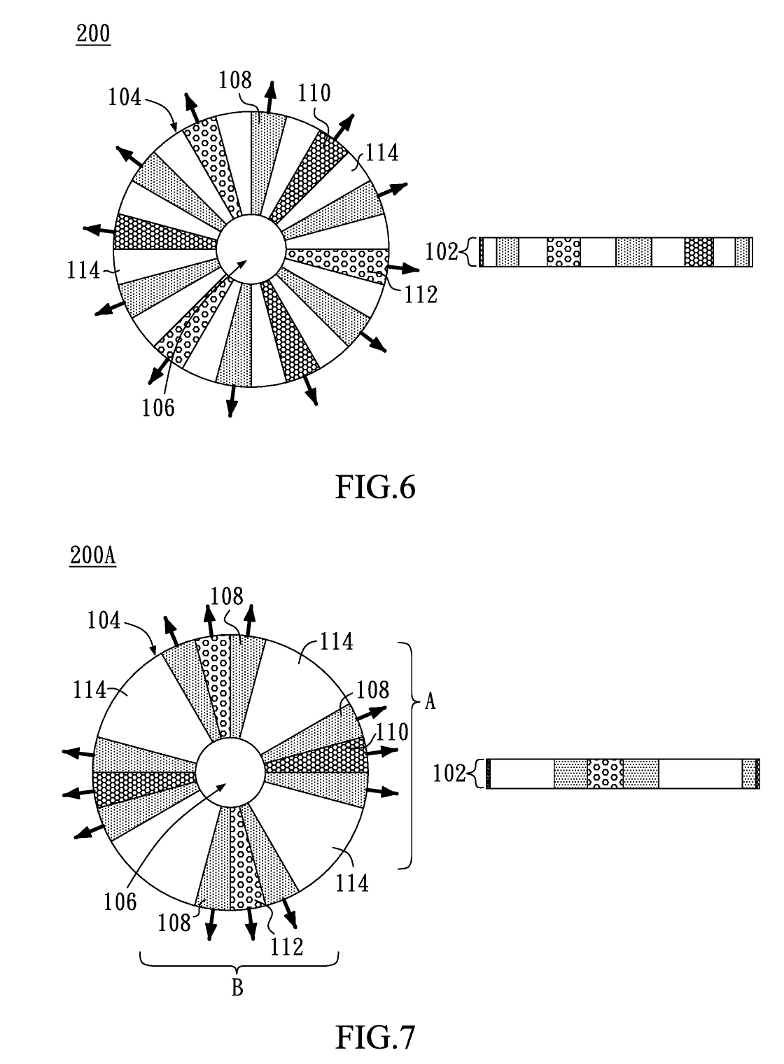

The gas distributing injector of the present invention may have a plurality of partitions to separate different gases channels. The partitions are used to dissipate heat and control the mixing time of the different reactant gases. FIG. 6 shows both top view and side view of a gas distributing injector 200 with partitions according to an embodiment of the present invention. Referring to FIG. 6, the gas distributing injector 200 comprises a gas distributing layer 102, which has a single layered configuration as mentioned before. The gas distributing layer 102 comprise a disk-shaped body 104, a plurality of first gas channel 108, a plurality of second gas channel 110, a plurality of third gas channel 112, and a plurality of partitions 114.

Referring to FIG. 6, each of the first gas channels 108 is interposed between two partitions 114 next to the first gas channel 108, each of the second gas channels 110 is interposed between two partitions 114 next to the second gas channel 110, and each of the third gas channels 112 is interposed between two partitions 114 next to the third gas channel 112. That is, each of the first, second, and third gas channels 108/110/112 is interposed between two partitions 114. The gas channels 108/110/112 and partitions 114 are arranged by a repeating period that clockwise orderly consists of one partition 114, one first gas channel 108, one partition 114, one second gas channel 110, one partition 114, and one third gas channel 112.

Referring to FIG. 6, the first gas channels 108, the second gas channels 110, the third gas channels 112, and the partitions 114 are symmetrically arranged on a same plane within the disk-shaped body 104 or the gas distributing layer 102.

Accordingly, various (reactant) gases are fed into the gas distributing injector 200 and are transported to the corresponding gas channel, such as the first gas channels 108, the second gas channels 110, and the third gas channels 112, through the mentioned gas distributing device (not shown). After that, various (reactant) gases are radially outwardly diffused from the center of the gas distributing injector 200 to the MOCVD reactor. Because the gases are separated by the partition 114, each of the (reactant) gases distributed by the gas distributing injector 200 needs a longer diffusion time for mixing with the other (reactant) gases than the diffusion time of the distributing injector shown in FIGS. 2-5B. Therefore, the partitions 114 can be used to control the diffusion period and the time when the reaction starts. In this embodiment, the number of the first gas channels 108, the second gas channel 110, the third gas channel 112, and the partitions 114 are 6, 3, 3, and 12, respectively. However, the number and position of each of those components should not be limited, and modification of number and position of those components should be within the scope of the present invention.

FIG. 7 shows both top view and side view of a gas distributing injector 200A with partitions according to another embodiment of the present invention. Referring to FIG. 7, the gas distributing injector 200A comprises a gas distributing layer 102, which has a single layered configuration as mentioned before. The gas distributing layer 102 comprises a disk-shaped body 104, a plurality of first gas channel 108, a plurality of second gas channel 110, a plurality of third gas channel 112, and a plurality of partitions 114. Two arrangements of the gas channels A and B are used in this embodiment. For arrangement A, two first gas channels 108 and one second gas channel 110 are interposed between two partitions 114. For arrangement B, two first gas channels 108 and one third gas channel 112 are interposed between two partitions 114. A partition 114 is shared between arrangement A and arrangement B. The gas channels 108/110/112 and partitions 114 are arranged by a repeating period that clockwise orderly consists of one partition 114, one first gas channel 108, one second gas channel 110, one first gas channel 108, one partition 114, one first gas channel 108, one third gas channel 112, and one first gas channel 108.

Modification of embodiment shown in FIG. 7 should be within the scope of the present invention. For arrangement A, the number of the second gas channel 110 interposed between two first gas channels 108 may not be one and may be two, three, or more. For arrangement B, the number of the third gas channel 112 interposed between two first gas channels 108 may not be one and may be two, three, or more. For arrangement A, the number of the first gas channel 108 interposed between two partitions 114 may be decreased to one from two, i.e., one first gas channel 108 and one second gas channel 110 being interposed between two partitions 114. In addition, the number of the first gas channel 108 or the number of the second gas channel 110 interposed between two partitions 114 can be increased to three, four, or more, and any combinations of the first gas channel 108 and the second gas channel 110 interposed between two partitions 114 should be within the scope of the present invention, as long as it obeys a rule that at least one first gas channel 108 and at least one second gas channel 110 are interposed between two partitions 114. For arrangement B, the number of the first gas channel 108 interposed between two partitions 114 may be decreased to one from two, i.e., one first gas channel 108 and one third gas channel 112 being interposed between two partitions 114. In addition, the number of the first gas channel 108 or the number of the third gas channel 112 interposed between two partitions 114 can be increased to three, four, or more, and any combinations of the first gas channel 108 and the third gas channel 112 interposed between two partitions 114 should be within the scope of the present invention, as long as it obeys a rule that at least one first gas channel 108 and at least one third gas channel 110 are interposed between two partitions 114.

In an alternative embodiment of FIG. 7, the arrangement A consists of two second gas channels 110 and one first gas channel 108 interposed between two partitions 114, and the arrangement B consists of two third gas channels 112 and one first gas channel 108 interposed between two partitions 114, wherein the first gas channel 108 is interposed between two second channels 110 for arrangement A, and the first gas channel 108 is interposed between two third channels 110 for arrangement B.

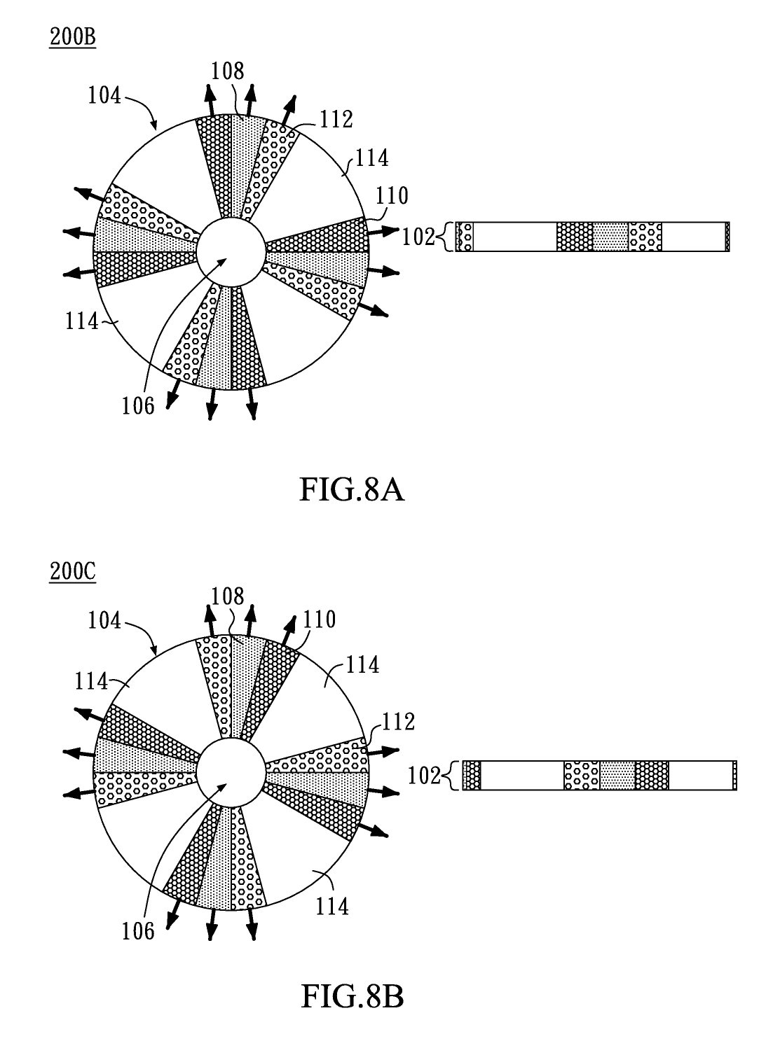

FIG. 8A shows both top view and side view of a gas distributing injector 200B with partitions according to another embodiment of the present invention. Referring to FIG. 8A, the gas distributing injector 200B comprises a gas distributing layer 102, which has a single layered configuration as mentioned before. Similarly, the gas distributing layer 102 comprises a disk-shaped body 104, a plurality of first gas channel 108, a plurality of second gas channel 110, a plurality of third gas channel 112, and a plurality of partitions 114.

In the embodiment of FIG. 8A, the arrangement of the first, second, third channels 108/110/112 and the partitions 114 obeys a rule that at least one first gas channel 108, at least one second channel 110, and at least one third gas channel 112 are interposed between the two partitions 114. Referring to FIG. 8A, one first gas channel 108, one second gas channel 110, and one third gas channel 112 are interposed between the two partitions 114, and wherein the first channel 108 is interposed between the second gas channel 110 and the third gas channel 112. The gas channels 108/110/112 and partitions 114 are arranged by a repeating period that clockwise orderly consists of one partition 114, one second gas channel 110, one first gas channel 108, and one third gas channel 112.

FIG. 8B shows both top view and side view of a gas distributing injector 200C with partitions according to another embodiment of the present invention. This embodiment is a modification of FIG. 8A. Referring to FIG. 8B, one first gas channel 108, one second gas channel 110, and one third gas channel 112 are interposed between the two partitions 114, and wherein the first channel 108 is interposed between the second gas channel 110 and the third gas channel 112. The gas channels 108/110/112 and partitions 114 are arranged by a repeating period that clockwise orderly consists of one partition 114, one third gas channel 112, one first gas channel 108, and one second gas channel 110.

In the embodiment of FIGS. 8A and 8B, the number of the first gas channel 108, the second gas channel 110, and the third gas channel 112 is not limited to one, and it can be increased to two or more, if necessary. For example, the gas channels 108/110/112 and partitions 114 are arranged by a repeating period that clockwise orderly consists of one partition 114, two second gas channels 110, two first gas channels 108, and two third gas channels 112. For example, the gas channels 108/110/112 and partitions 114 are arranged by a repeating period that clockwise orderly consists of one partition 114, two third gas channels 112, two first gas channels 108, and two second gas channels 110.

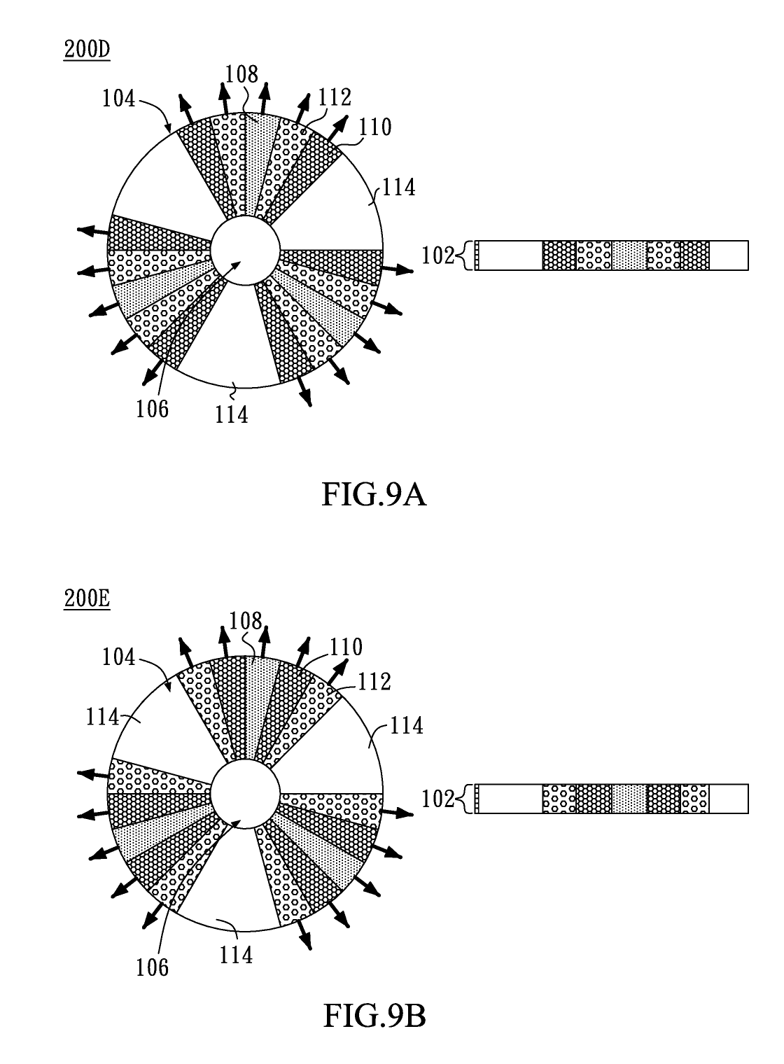

FIG. 9A shows both top view and side view of a gas distributing injector 200D with partitions according to another embodiment of the present invention. The gas channels 108/110/112 and partitions 114 are arranged by a repeating period that clockwise orderly consists of one partition 114, one second gas channel 110, one third gas channel 112, one first gas channel 108, one third gas channel 112, and one second gas channel 110.

FIG. 9B shows both top view and side view of a gas distributing injector 200E with partitions according to another embodiment of the present invention. The gas channels 108/110/112 and partitions 114 are arranged by a repeating period that clockwise orderly consists of one partition 114, one third gas channel 112, one second gas channel 110, one first gas channel 108, one second gas channel 110, and one third gas channel 112.

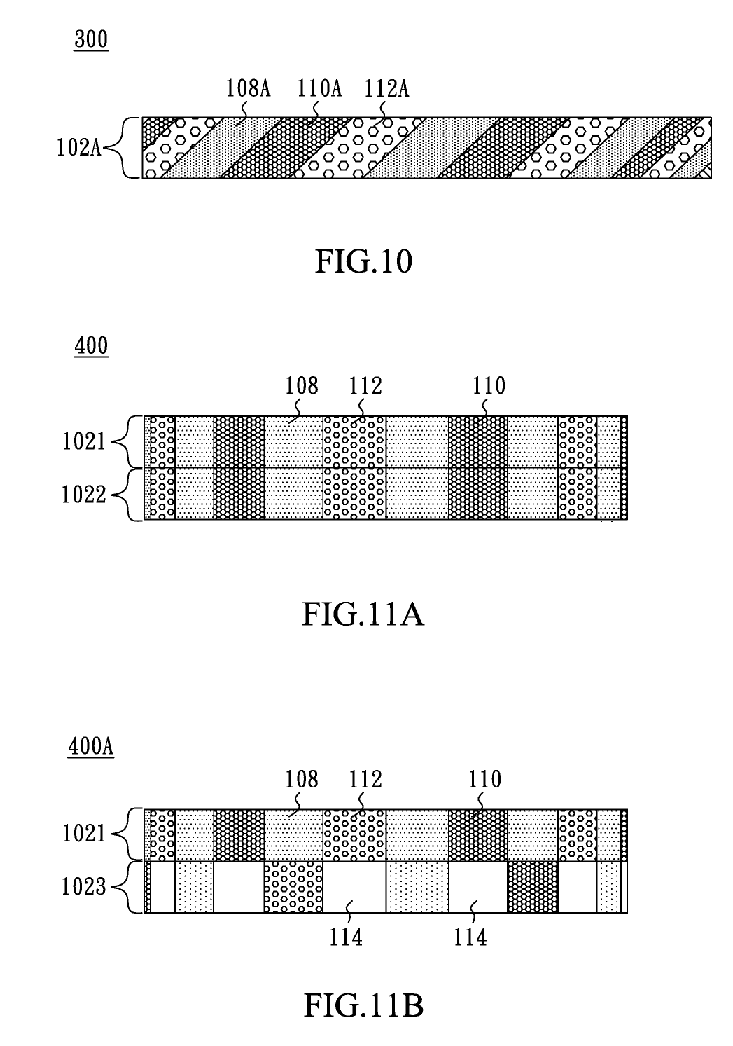

In the embodiments shown in FIGS. 2-9B, each of the first gas channels 108, the second gas channels 110, the third gas channels 112, and the partitions 114 has a cross-section that gradually increases from the center of the gas distributing layer 102 to the periphery of the gas distributing layer 102. In addition, the side walls of the first gas channels 108, the second gas channels 110, the third gas channels 112, and the partitions 114 are perpendicular to the top surface and bottom surface of the gas distributing layer 102 or the disk-shaped body 104. FIG. 10 is a side view showing a modified embodiment, in which the side walls of each of the first gas channels 108, the second gas channels 110, and the third gas channels 112 are not perpendicular to the top surface and bottom surface of the gas distributing layer 102A and an inclined angle is between each side wall of each of the first gas channels 108, the second gas channels 110, and the third gas channels 112 and top surface and bottom surface of the gas distributing layer 102A.

FIG. 11A is a side view showing a gas distributing injector 400 according to an embodiment of the present invention. In this embodiment, the gas distributing injector 400 has a multi-layered configuration. Referring to FIG. 11A, the gas distributing injector 400 has a first gas distributing layer 1021 stacked on a second gas distributing layer 1022. In an alternative embodiment, the second gas distributing layer 1022 is stacked on the first gas distributing layer 1021. The first gas distributing layer 1021 and the second gas distributing layer 1022 are similar to the gas distributing layers 102/102A as mentioned before, and similarly, each of the first gas distributing layer 1021 and the second gas distributing layer 1022 comprises first gas channels 108, second gas channels 110, and third gas channels 112. In addition, the arrangements of the first gas channels 108, the second gas channels 110, and the third gas channels are the same as the arrangement as shown in FIG. 2.

FIG. 11B is a side view showing a gas distributing injector 400A according to an embodiment of the present invention. In this embodiment, the gas distributing injector 400A has a multi-layered configuration. Referring to FIG. 11B, the gas distributing injector 400A has a first gas distributing layer 1021 stacked on a second gas distributing layer 1023. In an alternative embodiment, the second gas distributing layer 1023 is stacked on the first gas distributing layer 1021. The first gas distributing layer 1021 and the second gas distributing layer 1023 are similar to the gas distributing layers 102/102A as mentioned before, and similarly, each of the first gas distributing layer 1021 and the second gas distributing layer 1023 comprises first gas channels 108, second gas channels 110, and third gas channels 112. In addition, the arrangements of the first gas channels 108, the second gas channels 110, and the third gas channels of the first gas distributing layer 1021 are the same as the arrangement as shown in FIG. 2, and the arrangements of the first gas channels 108, the second gas channels 110, and the third gas channels of the second gas distributing layer 1023 are the same as the arrangement as shown in FIG. 6.

Accordingly, the present invention provides gas distributing injectors with single layered configuration that can distributing various gases on a same plane. The gas distributing injectors of the present invention have compact dimension and shorter diffusion time comparing with the conventional triple injector.

Although specific embodiments have been illustrated and described, it will be appreciated by those skilled in the art that various modifications may be made without departing from the scope of the present invention, which is intended to be limited solely by the appended claims.

What is claimed is:

1. A gas distributing injector applied in a Metal-Organic Chemical Vapor Deposition (MOCVD) reactor, comprising:
a gas distributing layer for transversely distributing various gases through a same plane, comprising:
a disk-shaped body having a hole at its center, the various gases being fed via the hole and a gas distributing device being placed within the hole for distributing the various gases;
a plurality of first gas channels radially outwardly extended from the center of the disk-shaped body to the periphery of the disk-shaped body, for transversely distributing a first gas of the various gases from the center of the disk-shaped body to the periphery of the disk-shaped body;
a plurality of second gas channels radially outwardly extended from the center of the disk-shaped body to the periphery of the disk-shaped body, for transversely distributing a second gas of the various gases from the center of the disk-shaped body to the periphery of the disk-shaped body; and
a plurality of third gas channels radially outwardly extended from the center of the disk-shaped body to the periphery of the disk-shaped body, for transversely distributing a third gas of the various gases from the center of the disk-shaped body to the periphery of the disk-shaped body;
wherein the first gas channels, the second gas channels, and the third gas channels are symmetrically arranged within the disk-shaped body and are arranged on the same plane, and the various gases are transversely distributed through the same plane.

2. The gas distributing injector as set forth in claim 1, wherein the first gas is a group III gas, the second gas is a group V gas, the third gas is a group V gas, and hydrogen gas or nitrogen gas is used as a carrier gas for the first gas, the second gas, and the third gas.

3. The gas distributing injector as set forth in claim 1, wherein at least one of the second gas channels or at least one of the third gas channels is interposed between every two of the first gas channels.

4. The gas distributing injector as set forth in claim 3, wherein the first gas channels, the second gas channels, and the third gas channels are arranged by a repeating period that orderly consists of one of the first gas channels, one of the second gas channels, one of the first gas channels, and one of the third gas channels.

5. The gas distributing injector as set forth in claim 1, wherein at least one of the second gas channels and at least one of the third gas channels are interposed between every two of the first gas channels.

6. The gas distributing injector as set forth in claim 5, wherein the interposed at least one of the second gas channels and at least one of the third gas channels are alternately arranged between every two of the first gas channels.

7. The gas distributing injector as set forth in claim 5, wherein two of the second gas channels and at least one of the third gas channels are interposed between every two of the first gas channels, and wherein the at least one third gas channel is interposed between the two second gas channels.

8. The gas distributing injector as set forth in claim 5, wherein two of the third gas channels and at least one of the second gas channels are interposed between every two of the first gas channels, and wherein the at least one second gas channel is interposed between the two third gas channels.

9. The gas distributing injector as set forth in claim 1, wherein the gas distributing layer further comprises a plurality partitions to separate the first gas channels, the second gas channels, and the third gas channels and control a diffusion time of the various gases.

10. The gas distributing injector as set forth in claim 9, wherein each of the first gas channels, the second gas channels, and the third gas channels is interposed between two partitions.

11. The gas distributing injector as set forth in claim 9, wherein the first gas channels, the second gas channels, the third gas channels, and the partitions are alternately arranged by a first repeating period and a second, repeating period, and wherein the first repeating period comprises at least one first gas channel and at least one second gas channel interposed between two partitions, and the second repeating period comprises at least one first gas channel and at least one third gas channel interposed between two partitions.

12. The gas distributing injector as set forth in claim 11, wherein the at least one second gas channel of the first repeating period is interposed between two first gas channels of the first repeating period.

13. The gas distributing injector as set forth in claim 11, wherein the at least one first gas channel of the first repeating period is interposed between two second gas channels of the first repeating period.

14. The gas distributing injector as set forth in claim 11, wherein the at least one third gas channel of the second repeating period is interposed between two first gas channels of the second repeating period.

15. The gas distributing injector as set forth in claim 11, wherein the at least one first gas channel of the second repeating period is interposed between two third gas channels of the second repeating period.

16. The gas distributing injector as set forth in claim 9, wherein at least one of the first gas channels, at least one of the second gas channels, and at least one of the third gas channels are interposed between two of the partitions.

17. The gas distributing injector as set forth in claim 16, wherein one of the first gas channels is interposed between one of the second gas channels and one of the third gas channels.

18. The gas distributing injector as set forth in claim 16, wherein one of the first gas channels is interposed between two of the second gas channels and the one of the first gas channel and the two of the second gas channel are interposed between two of the third gas channels.

19. The gas distributing injector as set forth in claim 16, wherein one of the first gas channels is interposed between two of the third gas channels and the one of the first gas channel and the two of the third gas channel are interposed between two of the second gas channels.

20. The gas distributing injector as set forth in claim 16, wherein the at least one second gas channel and the at least one third gas channel are interposed between every two of the first gas channels.

21. The gas distributing injector as set forth in claim 1, wherein each of the first gas channels, the second gas channels, and the third gas channels has side walls that are not perpendicular to a top surface and a bottom surface of the disk-shaped body.

22. The gas distributing injector as set forth in claim 1, further comprising a second gas distributing layer stacked on the gas distributing layer, the second gas distributing layer comprising a disk-shaped body, a plurality of first gas channels, a plurality of second gas channels, and a plurality of third gas channels.

23. The gas distributing injector as set forth in claim 22, wherein the arrangement of the first gas channels, the second gas channels, and the third gas channels of the second gas distributing layer is the same as the arrangement of the first gas channels, the second gas channels, and the third gas channels of the gas distributing layer.

24. The gas distributing injector as set forth in claim 22, wherein the arrangement of the first gas channels, the second gas channels, and the third gas channels of the second gas distributing layer is different than the arrangement of the first gas channels, the second gas channels, and the third gas channels of the gas distributing layer.
